(19) United States
(12) Patent Application Publication
(10) Pub. No.: US 2023/0208376 A1
(43) Pub. Date: Jun. 29, 2023

(54) METHOD OF MANUFACTURING AN ACOUSTIC WAVE DEVICE WITH THROUGH VIA ON MULTILAYER PIEZOELECTRIC SUBSTRATE

(71) Applicant: Skyworks Solutions, Inc., Irvine, CA (US)

(72) Inventors: Rei Goto, Osaka-Shi (JP); Hironori Fukuhara, Ibaraki-Shi (JP); Keiichi Maki, Suita-Shi (JP)

(21) Appl. No.: 18/064,860

(22) Filed: Dec. 12, 2022

Related U.S. Application Data
(60) Provisional application No. 63/294,543, filed on Dec. 29, 2021.
(60) Provisional application No. 63/294,578, filed on Dec. 29, 2021.

(51) Int. Cl. H03H 3/08; H03H 9/02; H03H 9/25; H03H 9/64

(52) U.S. Cl. CPC H03H 3/08; H03H 9/02574; H03H 9/25; H03H 9/6433

(57) ABSTRACT

A method of manufacturing a packaged acoustic wave component includes forming a support substrate, forming a multi-layer piezoelectric substrate over a first side of the support substrate, and forming one or more metal layers over a second side of the support substrate that is opposite the first side of the support substrate. The method also includes forming one or more surface acoustic wave resonators or filters (including a multi-mode surface acoustic wave resonator or filter) over the multi-layer piezoelectric substrate. The method also includes forming one or more vias through the support substrate, and electrically connecting the multi-mode surface acoustic wave resonator or filter and the metal layers with the vias to provide a ground connection for the multi-mode surface acoustic wave resonator or filter.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Technical Field

Embodiments of this disclosure relate to acoustic wave filters and, more specifically, to multi-mode surface acoustic wave filters with through vias on multilayer piezoelectric substrate, and to methods of manufacturing the same.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave filters include surface acoustic wave (SAW) filters and bulk acoustic wave (BAW) filters. A SAW resonator of a SAW filter typically includes an interdigital transductor electrode on a piezoelectric substrate. A SAW resonator is arranged to generate a surface acoustic wave. SAW filters include double mode SAW (DMS) filters.

### SUMMARY

In accordance with one aspect of the disclosure, a packaged acoustic wave component is provided. The packaged acoustic wave component comprises a support substrate and a multi-layer piezoelectric substrate disposed over a first side of the support substrate. One or more metal layers are disposed on a second side of the support substrate that is opposite the first side of the support substrate. One or more surface acoustic wave resonators or filters are disposed over the multi-layer piezoelectric substrate, the one or more surface acoustic wave resonators or filters including a multi-mode surface acoustic wave resonator or filter. One or more vias extend through the support substrate and are electrically connected to the multi-mode surface acoustic wave resonator or filter and the one or more metal layers to provide a ground connection for the multi-mode surface acoustic wave resonator or filter.

In accordance with another aspect of the disclosure, a radio frequency module is provided. The radio frequency module comprises a package substrate and a packaged acoustic wave component. The packaged acoustic wave component comprises a support substrate and a multi-layer piezoelectric substrate disposed over a first side of the support substrate. One or more metal layers are disposed on a second side of the support substrate that is opposite the first side of the support substrate. One or more surface acoustic wave resonators or filters are disposed over the multi-layer piezoelectric substrate, the one or more surface acoustic wave resonators or filters including a multi-mode surface acoustic wave resonator or filter. One or more vias extend through the support substrate and are electrically connected to the multi-mode surface acoustic wave resonator or filter and the one or more metal layers to provide a ground connection for the multi-mode surface acoustic wave resonator or filter. The radio frequency module also comprises additional circuitry, the packaged acoustic wave component and additional circuitry disposed on the package substrate.

In accordance with another aspect of the disclosure, a wireless communication device is provided. The wireless communication device comprises an antenna and a front end module including one or more packaged acoustic wave components configured to filter a radio frequency signal associated with the antenna. Each packaged acoustic wave component includes a support substrate and a multi-layer piezoelectric substrate disposed over a first side of the support substrate. One or more metal layers are disposed on a second side of the support substrate that is opposite the first side of the support substrate. One or more surface acoustic wave resonators or filters are disposed over the multi-layer piezoelectric substrate, the one or more surface acoustic wave resonators or filters including a multi-mode surface acoustic wave resonator or filter. One or more vias extend through the support substrate and are electrically connected to the multi-mode surface acoustic wave resonator or filter and the one or more metal layers to provide a ground connection for the multi-mode surface acoustic wave resonator or filter.

In accordance with another aspect of the disclosure, a method of manufacturing a packaged acoustic wave component is provided. The method comprises forming or providing a support substrate, forming or providing a multi-layer piezoelectric substrate over a first side of the support substrate, and forming or providing one or more metal layers over a second side of the support substrate that is opposite the first side of the support substrate. The method also comprises forming or providing one or more surface acoustic wave resonators or filters over the multi-layer piezoelectric substrate including forming or providing a multi-mode surface acoustic wave resonator or filter. The method also comprises forming or providing one or more vias through the support substrate, and electrically connecting the multi-mode surface acoustic wave resonator or filter and the one or more metal layers with the one or more vias to provide a ground connection for the multi-mode surface acoustic wave resonator or filter.

In accordance with another aspect of the disclosure, a method of manufacturing a packaged acoustic wave component is provided. The method includes forming or providing a support substrate, forming or providing a multi-layer piezoelectric substrate over a first side of the support substrate, and forming or providing one or more metal layers over a second side of the support substrate that is opposite the first side of the support substrate. The method also includes forming or providing one or more surface acoustic wave resonators or filters over the multi-layer piezoelectric substrate, including forming or providing a multi-mode surface acoustic wave resonator or filter. The method further includes forming or providing one or more unfilled vias through the support substrate that extend between an open end and a closed end, and electrically connecting the multi-mode surface acoustic wave resonator or filter and the one or more metal layers with the one or more vias to provide a ground connection for the multi-mode surface acoustic wave resonator or filter.

### BRIEF DESCRIPTION OF THE DRAWINGS

Embodiments of this disclosure will now be described, by way of non-limiting example, with reference to the accompanying drawings.

FIG. 1 is a schematic view of a package with a double mode surface acoustic wave (DMS) filter with an electrically connected bridge structure.

FIG. 1A is a cross-section of the package along line (a) in FIG. 1.

FIG. 1B is a cross-sectional view of the package along line (b) in FIG. 1.

FIG. 1C is a cross-sectional view of the package along line (c) in FIG. 1.

FIG. 2 is a schematic view of a package with a double mode surface acoustic wave (DMS) filter with an electrically connected bridge structure and through substrate vias (TSV).

FIG. 2A is a cross-section of the package along line (a) in FIG. 2.

FIG. 2B is a cross-sectional view of the package along line (b) in FIG. 2.

FIG. 2C is a cross-sectional view of the package along line (c) in FIG. 2.

FIG. 3 is a schematic view of a package with a multi-mode surface acoustic wave (MMS) filter with through substrate vias (TSV).

FIG. 3A is a cross-section of the package along line (a) in FIG. 3.

FIG. 3B is a cross-sectional view of the package along line (b) in FIG. 3.

FIG. 3C is a cross-sectional view of the package along line (c) in FIG. 3.

FIG. 4 is a graph of transmission characteristics versus frequency.

FIG. 5 is a schematic view of a package with a multi-mode surface acoustic wave (MMS) filter with through substrate vias (TSV).

FIG. 6 is a schematic view of a package with a multi-mode surface acoustic wave (MMS) filter with through substrate vias (TSV).

FIG. 7 is a schematic view of a package with a multi-mode surface acoustic wave (MMS) filter with through substrate vias (TSV).

FIG. 8 is a cross-sectional side view of a package with hollow vias in the substrate.

FIG. 9 is a cross-sectional side view of a package with hollow vias in the substrate.

FIG. 10 is a schematic diagram of a radio frequency module that includes a MMS filter.

FIG. 11 is a schematic diagram of a radio frequency module that includes a MMS filter.

FIG. 12A is a schematic block diagram of a wireless communication device that includes a MMS filter.

FIG. 12B is a schematic block diagram of another wireless communication device that includes a MMS filter.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) resonators. The speed at which an acoustic wave will propagate within a SAW resonator is a function of a variety of factors, including the thicknesses of the various components and the density of the materials used to form the various components.

A plurality of resonators may be formed on a single wafer, including filter components of different types. For example, a single wafer may include one or more multi-mode SAW (MMS) filters, in addition to one or more SAW resonators. These components may have different design, but may share common manufacturing steps, and may therefore share common constituent layers. The use of thicker layers and/or denser materials in an interdigital transducer (IDT) electrode of a SAW resonator can slow the propagation of acoustic waves within the SAW resonators, allowing the SAW resonators to be made more compact. However, the use of these thicker layers or denser materials in IDT electrodes may not be suitable for use in the longitude coupled multi-mode SAW (MMS) filters. In one implementation, a MMS filter can be a double mode surface acoustic wave (DMS) filter. DMS filters can be receive filters arranged to filter radio frequency signals received by an antenna. DMS filters can be temperature compensated by including a temperature compensation layer, such as a silicon dioxide (SiO₂) layer, over interdigital transducer (IDT) electrodes. Such a temperature compensating layer can cause a temperature coefficient of frequency (TCF) of a DMS filter to be closer to zero.

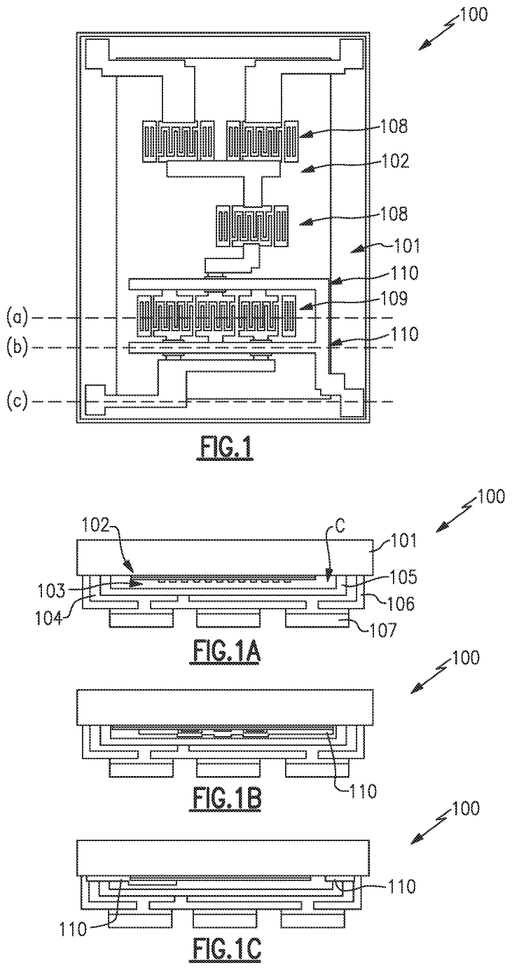

FIGS. 1 illustrates a packaged acoustic wave component 100 (e.g., a chip scale package or CSP), hereafter referred to as the “package”, and FIGS. 1A-1C illustrate cross-sections of the package 100 at different locations as shown. The package 100 includes a support substrate 101, a multi-layer piezoelectric substrate (MPS) 102 disposed on the support substrate 101, and one or more interdigital transducer (IDT) electrodes 103 disposed on the MPS 102. The package 100 also includes a metal portion 104 in thermal contact with the support substrate 101 and spaced from the MPS 102 and IDT electrodes 103 by a cavity C (e.g., open or hollow cavity, air cavity). A dielectric layer 105 is disposed over at least a portion of the metal portion 104 (e.g., so that the dielectric layer 105 is between the metal portion 104 and the cavity C. In one implementation, the dielectric layer 105 can be a polyimide layer. A dielectric overcoat 106 is disposed over at least a portion of the metal portion 104. One or more solder connections 107 are disposed on the metal portion 104 so that the metal portion is between the solder connection(s) 107 and the rest of the package 100.

The one or more IDT electrodes 103 of the package 100 are part of one or more SAW resonators or filters 108 and a double mode SAW (DMS) resonator or filter 109. The package 100 includes a metal bridge structure 110 to connect the DMS filter 109 to ground (e.g., via the metal portion 104 and solder connections 107). One drawback of the metal bridge structure 110 to connect the DMS filter 109 to ground is that it results in parasitic inductance, which affects the performance of the DMS filter 109 since the DMS performance is sensitive to parasitic inductance to ground. Additionally, use of the metal bridge structure 110 limits where on the package 100 the DMS filter 109 can be located in order to connect to ground since the bridge connects to ground on the edge of the package or chip 100.

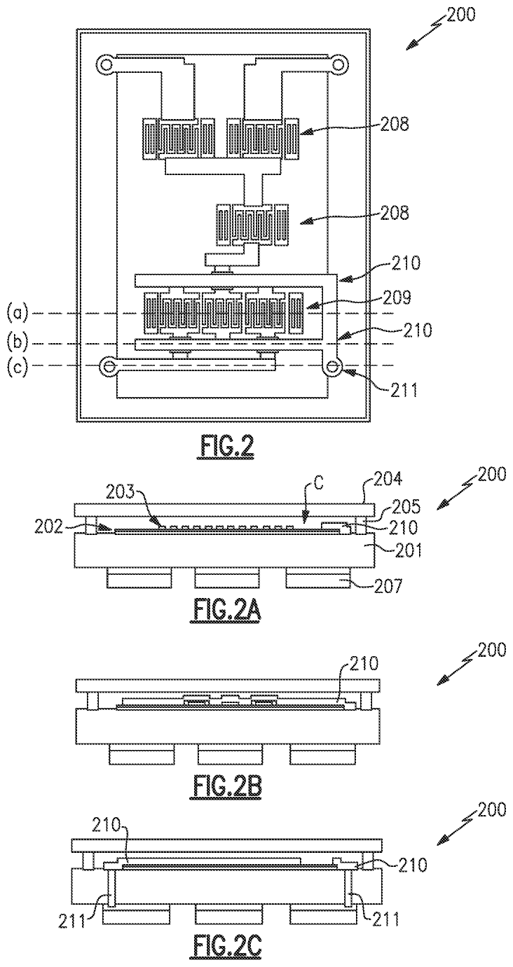

FIGS. 2 illustrates a packaged acoustic wave component 200, hereafter referred to as the “package”, and FIGS. 2A-2C illustrate cross-sections of the package 200 at different locations as shown. The package 200 includes a support substrate 201, a multilayer piezoelectric substrate (MPS) 202 disposed on the support substrate 201, and one or more interdigital transducer (IDT) electrodes 203 disposed on the MPS 202. The package 200 also includes a cap (e.g., cap wafer) 204 in thermal contact with the support substrate 201 by way of one or more vias or posts 205. The cap 204 is spaced from the MPS 202 and IDT electrodes 203 by a cavity C (e.g., open or hollow cavity, air cavity). One or more solder connections 207 are disposed on an opposite side of the support substrate 201 from the MPS 202 and IDT electrodes 203 so that the support substrate 201 is interposed between the solder connection(s) 207 and the rest of the package 200.

The one or more IDT electrodes 203 of the package 200 are part of one or more SAW resonators or filters 208 and a double mode SAW (DMS) resonator or filter 209. The package 200 includes a metal bridge structure 210 to connect the DMS filter 209 to the solder connections 207 (and thereby to ground) by way of one or more vias 211 that extend through the support substrate 201 (e.g., through substrate vias or TSVs), as shown in FIG. 2C. The metal bridge structure 210 to connect the DMS filter 209 to ground (via the solder connections 207) also results in parasitic inductance, which affects the performance of the DMS filter 209. Additionally, use of the metal bridge structure 210 limits where on the package 200 the DMS filter 209 can be located in order to connect to ground since the bridge connects to ground on the edge of the package or chip 200.

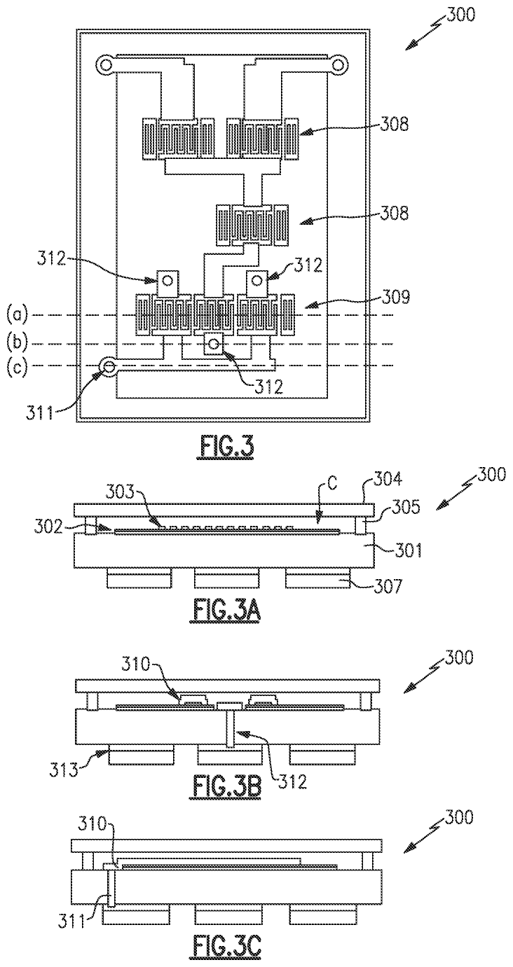

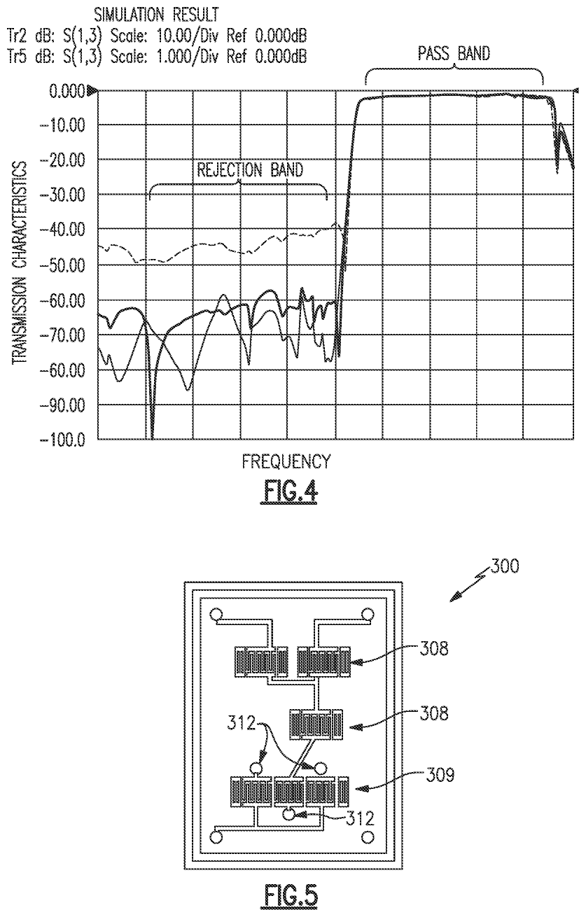

FIGS. 3 illustrates a packaged acoustic wave component 300, hereafter referred to as the “package”, and FIGS. 3A-3C illustrate cross-sections of the package 300 at different locations as shown. The package 300 in FIGS. 3-3C is similar to the package 200 in FIGS. 2-2C, except as discussed below. Thus, reference numerals used to designate the various components of the package 300 are identical to those used for identifying the corresponding components of the package 200 of FIGS. 2-2C, except that the numerical identifier begins with a “3” instead of a “2” (e.g., 301 instead of 201). Accordingly, the structure and description for the various features of the package 200 in FIGS. 2-2C are understood to also apply to the corresponding features of the package 200 in FIGS. 3-3C, except as described below.

The package 300 in FIGS. 3-3C differs from the package 200 in FIGS. 2-2C in that the package 300 does not have a metal bridge structure (e.g., like the metal bridge structure 210). Rather, a multi-mode SAW (MMS) resonator or filter 309 connects directly to ground (via the solder connections 307) by way of a via 312 that extends through the support substrate 301 (e.g., a through-substrate via or TSV). In one implementation, the MMS resonator or filter 309 is a dual mode SAW (DMS) resonator or filter. In the illustrated implementation, one of the vias 312 can be a ground connection for an input to the MMS resonator of filter 309 and two other vias 312 can be ground connections for an output to the MMS resonator or filter 309. The support substrate 301 can in one implementation be made of silicon. The package 300 can have a metal layer 313 under the vias 312 (e.g., a metal layer 313 between the solder connections 307 and the via 312). In one implementation, metal layer 310 (see FIG. 3B) is disposed over the connections of the MMS resonator or filter 309, which can reduce conductive loss. In another implementation, the metal layer 310 over the connections of the MMS resonator or filter 309 can be excluded (but may result in higher conductive loss).

Advantageously, use of the through-substrate vias 312 to connect the MMS resonator or filter 309 and ground reduces the parasitic inductance, and therefore reduces the effect of parasitic inductance on the performance of the MMS resonator or filter (e.g., DMS resonator or filter) 309. Additionally, use of the through-substrate vias 312 advantageously allows the MMS resonator or filter 309 (e.g., DMS resonator or filter) to be located anywhere on the package 300 because can connect to ground by way of via through the support substrate 301. Another advantage provided by the package 300 is a simpler manufacturing process because the steps necessary in including a metal bridge structure are not needed.

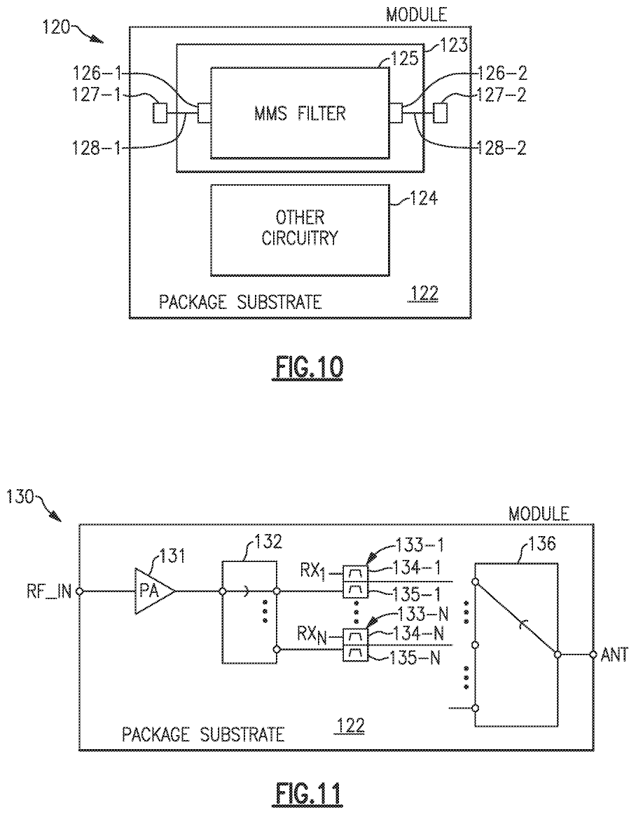

In one implementation, the package 300 can be manufactured using a method or process that includes forming or providing the support substrate 301, forming or providing the MPS 302 on a first side of the support substrate 301, and forming or providing one or more SAW resonators or filters 308 and a multi-mode SAW (MMS) resonator or filter 309 on the MPS 302, where the one or more SAW resonators or filters 308 and multi-mode SAW (MMS) resonator or filter 309 include IDT electrodes 303. The method can also include forming or attaching one or more posts or vias 305 to the first side of the support substrate 301, and attaching a cap to the posts or vias 305 so that a cavity C is defined between the cap 304 and the MPS 302. The method or process can also include the step of forming one or more vias (through-substrate vias or TSVs) 312 through the support substrate 301 from a second side of the support substrate 301 toward the first side of the support substrate 301 so that they are electrically and thermally connected to the MMS resonator or filter 309 (e.g., DMS resonator or filter), forming or providing a metal layer 313 over the second side of the support substrate 301 so that it is electrically and thermally connected to the TSVs 312, and forming or providing one or more solder connections 307 in contact with the metal layer 313. Optionally, the TSVs 312 can be unfilled (as described further below in connection with FIGS. 8 and 9).

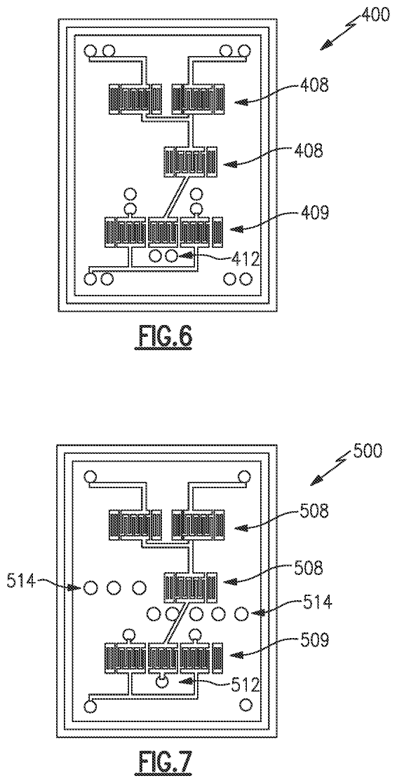

FIG. 4 shows a graph of the performance of the packages 100, 200 and 300 relative to frequency. The dashed line represents the performance of the package 100, the dark solid line represents the performance of the package 200, and the light solid line represents the performance of the package 300. The graph shows that the package 300 has better attenuation performance than the packages 100 and 200. For example, in the rejection band, the package 300 has a better performance (e.g., better floor level), with the package 100 having the worst performance as compared with the packages 200 and 300.

FIG. 5 is schematic representation of the package 300 discussed above in connection with FIGS. 3-3C. Thus, reference numerals used to designate the various components of the package 300 in FIG. 5 are identical to those used for identifying the corresponding components of the package 300 of FIGS. 3-3C. Accordingly, the structure and description for the various features of the package 300 in FIGS. 3-3C are understood to also apply to the corresponding features of the package 300 in FIG. 5.

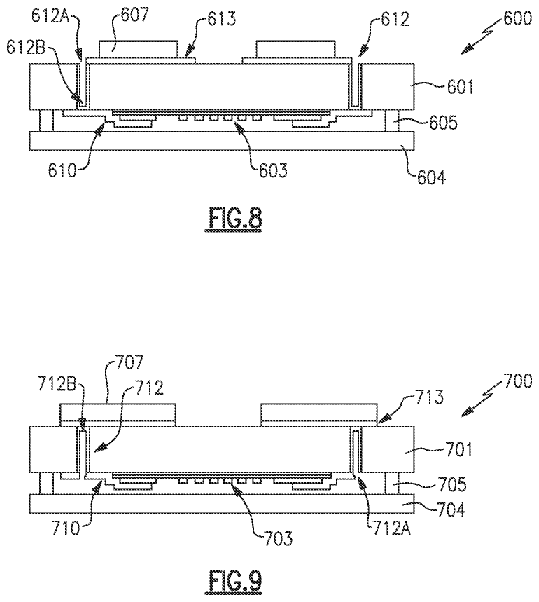

FIG. 6 illustrates a packaged acoustic wave component 400, hereafter referred to as the “package”. The package 400 in FIG. 6 is similar to the package 300 in FIGS. 3-3C and 5, except as discussed below. Thus, reference numerals used to designate the various components of the package 400 are identical to those used for identifying the corresponding components of the package 300 of FIGS. 3-3C and 5, except that the numerical identifier begins with a “4” instead of a “3” (e.g., 412 instead of 312). Accordingly, the structure and description for the various features of the package 300 in FIGS. 3-3C and 5 are understood to also apply to the corresponding features of the package 400 in FIG. 6, except as described below.

The package 400 in FIG. 6 differs from the package 300 in FIGS. 3-3C and 5 in that it includes multiple vias (e.g., two) 412 at each location instead of one via at each location. Advantageously, the use of multiple vias 412 at each location results in a reduction of resistive loss.

FIG. 7 illustrates a packaged acoustic wave component 500, hereafter referred to as the “package”. The package 500 in FIG. 7 is similar to the package 300 in FIGS. 3-3C and 5, except as discussed below. Thus, reference numerals used to designate the various components of the package 500 are identical to those used for identifying the corresponding components of the package 300 of FIGS. 3-3C and 5, except that the numerical identifier begins with a “5” instead of a “3” (e.g., 512 instead of 312). Accordingly, the structure and description for the various features of the package 300 in FIGS. 3-3C and 5 are understood to also apply to the corresponding features of the package 500 in FIG. 7, except as described below.

The package 500 in FIG. 7 differs from the package 300 in FIGS. 3-3C and 5 in that it includes one or more arrays (e.g., linear rows) of vias 514. The one or more arrays (e.g. linear rows) of vias 514 advantageously provide improved transmit/receive (Tx/Rx) isolation (e.g. inter-filter isolation) performance. In one implementation, the one or more arrays (e.g., linear rows) of vias 514 allow the formation of a sealed structure for the package 500.

FIG. 8 illustrates a packaged acoustic wave component 600, hereafter referred to as the “package”. The package 600 in FIG. 8 is similar to the package 300 in FIGS. 3-3C and 5, except as discussed below. Thus, reference numerals used to designate the various components of the package 600 are identical to those used for identifying the corresponding components of the package 300 of FIGS. 3-3C and 5, except that the numerical identifier begins with a “6” instead of a “3” (e.g., 601 instead of 301). Accordingly, the structure and description for the various features of the package 300 in FIGS. 3-3C and 5 are understood to also apply to the corresponding features of the package 600 in FIG. 8, except as described below.

The package 600 in FIG. 8 differs from the package 300 in FIGS. 3-3C and 5 in that the through-substrate vias 612 are not filled (e.g., are open) and extend from an open end 612A at a side of the support substrate 601 that is opposite the IDT electrode 603 to a closed end 612B adjacent (e.g., in contact with) the metal later 610. The via 612 is defined by a metal layer that is adjacent the bore formed in the support substrate 601 (e.g., has a hollow cylindrical shape) and contacts (e.g., directly contacts) the metal layer 613 under the solder connection 607 and the metal layer 610 over the resonator or filter. Having the through-substrate vias 612 unfilled advantageously simplifies the fabrication process of the package 600 because the number of process steps are reduced. Additionally, having the through-substrate vias 612 unfilled advantageously allows optical inspection of the connectivity of the vias 612 (e.g., allows the inspection of the closed end 612B connection to the metal layer 610). Any of the packages 300, 400, 600 described above can have vias that are unfilled as described in connection with FIG. 8.

FIG. 9 illustrates a packaged acoustic wave component 700, hereafter referred to as the “package”. The package 700 in FIG. 9 is similar to the package 600 in FIG. 8, which is based on the package 300 in FIGS. 3-3C and 5, except as discussed below. Thus, reference numerals used to designate the various components of the package 700 are identical to those used for identifying the corresponding components of the package 600 of FIG. 8, except that the numerical identifier begins with a “7” instead of a “6” (e.g., 701 instead of 601). Accordingly, the structure and description for the various features of the package 600 in FIG. 8, which is based on the structure and description of the package 300 in FIGS. 3-3C and 5, are understood to also apply to the corresponding features of the package 700 in FIG. 9, except as described below.

The package 700 in FIG. 9 differs from the package 600 in FIG. 8 in that the open end 712A of the through-substrate vias 712 is on the device side (e.g., is on the side of the support substrate 701 that is opposite the solder connections 707, and the closed end 712B of the through-substrate vias (TSVs) 712 is adjacent (e.g. in contact with) the metal layer 713 under the solder connection 707.

FIG. 10 is a schematic diagram of a radio frequency module 120 that includes a SAW component 123. The illustrated radio frequency module 120 includes the SAW component 123 and other circuitry 124. SAW component 123 includes a MMS filter 125 (e.g., a dual mode SAW filter) that can include any suitable combination of features of the MMS filters disclosed herein. The SAW component 123 includes a SAW die that includes SAW resonators. The SAW resonators include the resonators of the MMS filter 125. The SAW resonators can include additional SAW resonators.

The SAW component 123 shown in FIG. 10 includes the MMS filter 125 and terminals 126-1 and 126-2. The terminals 126-1 and 126-2 can serve, for example, as an input contact and an output contact. The SAW component 123 and the other circuitry 124 are on a common packaging substrate 122 in FIG. 10. The package substrate 122 can be a laminate substrate. The terminals 126-1 and 126-2 can be electrically connected to contacts 127-1 and 127-2, respectively, on the packaging substrate 122 by way of electrical connectors 128-1 and 128-2, respectively. The electrical connectors 128-1 and 128-2 can be bumps or wire bonds, for example.

The other circuitry 124 can include any suitable additional circuitry. For example, the other circuitry can include one or more power amplifiers, one or more radio frequency switches, one or more additional filters, one or more low noise amplifiers, the like, or any suitable combination thereof. The radio frequency module 120 can include one or more packaging structures to, for example, provide protection and/or facilitate easier handling of the radio frequency module 120. Such a packaging structure can include an overmold structure formed over the packaging substrate 122. The overmold structure can encapsulate some or all of the components of the radio frequency module 120.

FIG. 11 is a schematic diagram of a radio frequency module 130 that includes a MMS filter. As illustrated, the radio frequency module 130 includes a power amplifier 131, a select switch 132, duplexers 133-1 to 133-N that include receive filters 134-1 to 134-N and respective transmit filters 135-1 to 135-N, and an antenna switch 136. The radio frequency module 130 can include a package that encloses the illustrated elements. The illustrated elements can be disposed on a common packaging substrate 122. The packaging substrate can be a laminate substrate, for example.

The duplexers 133-1 to 133-N can each include two acoustic wave filters coupled to a common node. The two acoustic wave filters can be a transmit filter and a receive filter. As illustrated, the transmit filter and the receive filter can each be a band pass filter arranged to filter a radio frequency signal. One or more of the receive filters 134-1 to 134-N can include a MMS filter in accordance with any suitable principles and advantages disclosed herein. Although FIG. 11 illustrates duplexers, any suitable principles and advantages disclosed herein can be implemented in other multiplexers (e.g., quadplexers, hexaplexers, octoplexers, etc.) and/or in switch-plexers.

The power amplifier 131 can amplify a radio frequency signal. The illustrated switch 132 is a multi-throw radio frequency switch. The switch 132 can electrically couple an output of the power amplifier 131 to a selected transmit filter of the transmit filters 135-1 to 135-N. In some instances, the switch 132 can electrically connect the output of the power amplifier 131 to more than one of the transmit filters 135-1 to 135-N. The receive filters 134-1 to 135-N can be coupled to one or more low noise amplifiers. In some instances, a switch can selectively couple one or more of the receive filters 134-1 to 135-N to a low noise amplifier. According to certain applications, one or more of the receive filters 134-1 to 135-N can be electrically connected to a respective a low noise amplifier without an intervening switch. In some instances, the radio frequency module 130 can include one or more low noise amplifiers. Alternatively or additionally, one or more low noise amplifiers in communication with one or more of the receive filters 134-1 to 135-N can be external to the module 130. The antenna switch 136 can selectively couple a signal from one or more of the duplexers 131-1 to 131-N to an antenna port ANT. The duplexers 131-1 to 131-N can be associated with different frequency bands and/or different modes of operation (e.g., different power modes, different signaling modes, etc.).

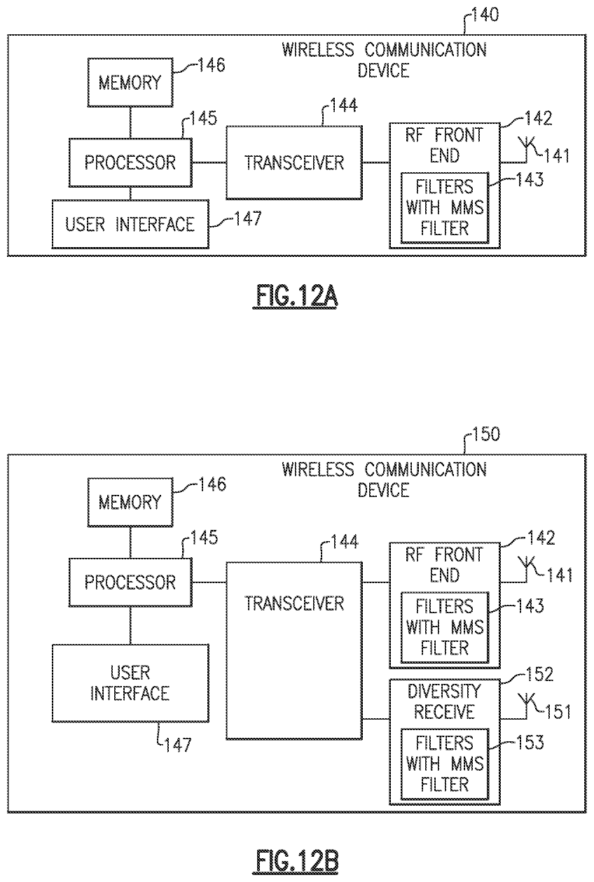

FIG. 12A is a schematic diagram of a wireless communication device 140 that includes a MMS filter 143 in a radio frequency front end 142 according to an embodiment. The MMS filter 143 can be implemented in accordance with any suitable principles and advantages disclosed herein. The wireless communication device 140 can be any suitable wireless communication device. For instance, a wireless communication device 140 can be a mobile phone, such as a smart phone. As illustrated, the wireless communication device 140 includes an antenna 141, an RF front end 142, a transceiver 144, a processor 145, a memory 146, and a user interface 147. The antenna 141 can transmit RF signals provided by the RF front end 142. The antenna 141 can receive RF signals. The received RF signals can be provided to the RF front end 142.

The RF front end 142 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 142 can transmit and receive RF signals associated with any suitable communication standards. The MMS filter 143 can be arranged as a receive filter configured to filter an RF signal received via the antenna 141. The MMS filter 143 can include acoustic reflectors arranged in accordance with any principles and advantages disclosed herein.

The transceiver 144 can provide RF signals to the RF front end 142 for amplification and/or other processing. The transceiver 144 can also process an RF signal provided by a low noise amplifier of the RF front end 142. The transceiver 144 is in communication with the processor 145. The processor 145 can be a baseband processor. The processor 145 can provide any suitable base band processing functions for the wireless communication device 140. The memory 146 can be accessed by the processor 145. The memory 146 can store any suitable data for the wireless communication device 140. The user interface 147 can be any suitable user interface, such as a display with touch screen capabilities.

FIG. 12B is a schematic diagram of a wireless communication device 150 that includes filters 143 in a radio frequency front end 142 and a second MMS filter 153 in a diversity receive module 152. The wireless communication device 150 is like the wireless communication device 140 of FIG. 12A, except that the wireless communication device 150 also includes diversity receive features. As illustrated in FIG. 12B, the wireless communication device 150 includes a diversity antenna 151, a diversity module 152 configured to process signals received by the diversity antenna 151 and including MMS filter 153, and a transceiver 154 in communication with both the radio frequency front end 142 and the diversity receive module 152. The MMS filter 153 can filter a radio frequency signal received via the diversity antenna 151. The MMS filter 153 can include acoustic reflectors arranged in accordance with any principles and advantages disclosed herein.

Any of the embodiments described above can be implemented in association with mobile devices such as cellular handsets. The principles and advantages of the embodiments can be used for any systems or apparatus, such as any uplink cellular device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals having a frequency in a range from about 30 kHz to 300 GHz, such as a frequency in a range from about 450 MHz to 8.5 GHz.

An acoustic wave resonator including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more acoustic wave resonators disclosed herein. FR1 can be from 410 MHz to 7.125 GHz, for example, as specified in a current 5G NR specification. One or more acoustic wave resonators in accordance with any suitable principles and advantages disclosed herein can be included in a filter arranged to filter a radio frequency signal in a fourth generation (4G) Long Term Evolution (LTE) operating band and/or in a filter with a passband that spans a 4G LTE operating band and a 5G NR operating band.

Aspects of this disclosure can be implemented in various electronic devices. Examples of the electronic devices can include, but are not limited to, consumer electronic products, parts of the consumer electronic products such as die and/or acoustic wave filter assemblies and/or packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a personal digital assistant (PDA), a microwave, a refrigerator, an automobile, a stereo system, a DVD player, a CD player, a digital music player such as an MP3 player, a radio, a camcorder, a camera, a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method of manufacturing a packaged acoustic wave component, the method comprising:
forming or providing a support substrate;
forming or providing a multi-layer piezoelectric substrate over a first side of the support substrate;
forming or providing one or more metal layers over a second side of the support substrate that is opposite the first side of the support substrate;
forming or providing one or more surface acoustic wave resonators or filters over the multi-layer piezoelectric substrate, including forming or providing a multi-mode surface acoustic wave resonator or filter;
forming or providing one or more vias through the support substrate; and
electrically connecting the multi-mode surface acoustic wave resonator or filter and the one or more metal layers with the one or more vias to provide a ground connection for the multi-mode surface acoustic wave resonator or filter.

2. The method of claim 1 wherein forming or providing a multi-mode surface acoustic wave resonator or filter includes forming or providing a dual mode surface acoustic wave resonator or filter.

3. The method of claim 1 further comprising forming or providing a cap wafer and supporting the cap wafer over the support substrate with one or more vias such that a cavity is defined between the cap wafer and the support substrate.

4. The method of claim 1 wherein electrically connecting the multi-mode surface acoustic wave resonator or filter and the one or more metal layers includes electrically connecting a second metal layer disposed over an electrical connection of the multi-mode surface acoustic wave resonator or filter with the one or more vias.

5. The method of claim 1 wherein forming or providing the one or more vias includes forming or providing a pair of vias at each electrical connection location to provide a reduction in resistive loss.

6. The method of claim 1 wherein forming or providing the one or more vias includes forming or providing a linear array of vias configured to facilitate inter-filter isolation.

7. The method of claim 1 wherein forming or providing the one or more vias includes forming or providing one or more vias that are unfilled.

8. The method of claim 1 further comprising forming or providing one or more solder connections and attaching the one or more solder connections to the one or more metal layers.

9. A method of manufacturing a packaged acoustic wave component, the method comprising:
forming or providing a support substrate;
forming or providing a multi-layer piezoelectric substrate over a first side of the support substrate;
forming or providing one or more metal layers over a second side of the support substrate that is opposite the first side of the support substrate;
forming or providing one or more surface acoustic wave resonators or filters over the multi-layer piezoelectric substrate, including forming or providing a multi-mode surface acoustic wave resonator or filter;
forming or providing one or more unfilled vias through the support substrate that extend between an open end and a closed end; and
electrically connecting the multi-mode surface acoustic wave resonator or filter and the one or more metal layers with the one or more vias to provide a ground connection for the multi-mode surface acoustic wave resonator or filter.

10. The method of claim 9 wherein forming or providing a multi-mode surface acoustic wave resonator or filter includes forming or providing a dual mode surface acoustic wave resonator or filter.

11. The method of claim 9 further comprising forming or providing a cap wafer and supporting the cap wafer over the support substrate with one or more vias such that a cavity is defined between the cap wafer and the support substrate.

12. The method of claim 9 wherein electrically connecting the multi-mode surface acoustic wave resonator or filter and the one or more metal layers includes electrically connecting a second metal layer disposed over an electrical connection of the multi-mode surface acoustic wave resonator or filter with the one or more vias.

13. The method of claim 9 wherein forming or providing the one or more vias includes forming or providing a pair of vias at each electrical connection location to provide a reduction in resistive loss.

14. The method of claim 9 wherein forming or providing the one or more vias includes forming or providing a linear array of vias configured to facilitate inter-filter isolation.

15. The method of claim 9 further comprising forming or providing one or more solder connections and attaching the one or more solder connections to the one or more metal layers.

16. The method of claim 9 wherein the open end of the one or more vias is on the second side of the support substrate and the closed end of the one or more vias is on the first side of the support substrate.

17. The method of claim 9 wherein the open end of the one or more vias is on the first side of the support substrate and the closed end of the one or more vias is on the second side of the support substrate.
